(19) United States
(12) Patent Application Publication
(10) Pub. No.: US 2017/0170220 A1
(43) Pub. Date: Jun. 15, 2017

(54) IMAGE SENSOR HAVING HYBRID COLOR FILTER

(71) Applicant: SAMSUNG ELECTRONICS CO., LTD., Suwon-si (KR)

(72) Inventors: Sunghyun NAM, Yongin-si (KR); Sookyoung ROH, Seoul (KR); Seokho YUN, Hwaseong-si (KR)

(73) Assignee: SAMSUNG ELECTRONICS CO., LTD., Suwon-si (KR)

(21) Appl. No.: 15/378,751

(22) Filed: Dec. 14, 2016

(30) Foreign Application Priority Data
Dec. 14, 2015 (KR) 10-2015-0178506

(51) Int. Cl. H01L 27/146

(52) U.S. Cl. CPC H01L 27/14621; H01L 27/14625; H01L 27/14627; H01L 27/1462; H01L 27/14605

(57) ABSTRACT

An image sensor includes a photoelectric conversion layer, and color filters disposed on the photoelectric conversion layer and respectively in pixel regions, the color filters including a blue filter, a red filter, and a broad green filter. The blue filter includes an organic material, the red filter includes an organic material, and the broad green filter includes sub-micron structures including an inorganic material and disposed on the photoelectric conversion layer, and a dielectric layer covering the sub-microns structures, each of the sub-micron structures having a refractive index greater than a refractive index of the dielectric layer.

### CROSS-REFERENCE TO RELATED APPLICATION

This application claims priority from Korean Patent Application No. 10-2015-0178506, filed on Dec. 14, 2015, in the Korean Intellectual Property Office, the disclosure of which is incorporated herein by reference in its entirety.

### BACKGROUND

1. Field

Apparatuses consistent with exemplary embodiments relate to image sensors having hybrid color filters.

2. Description of the Related Art

A color image sensor detects a color of incident light via a color filter. The color image sensor mostly uses, for example, an RGB color filter method known as a Bayer pattern, in which green filters are arranged in two pixels and a red filter and a blue filter are respectively arranged in the remaining two pixels of a unit pixel that includes four pixels. Besides the RGB color filter method, a CYGM color filter method is also used, in which four color filters of cyan, yellow, green, and magenta colors that complement each other are arranged in four pixels of a unit pixel.

Because a color filter absorbs light except for light of a color, the color filter reduces light utilization efficiency. For example, when a RGB color filter is used, the RGB color filter only transmits approximately ⅓ of incident light and absorbs ⅔ of the incident light, and thus, the light utilization efficiency is very low. Accordingly, in a color image sensor, most of light loss occurs at the color filter. As such, it may be difficult to obtain a clear image under illumination conditions of low intensity.

Recently, to increase the light utilization efficiency of a color image sensor, attempts have been conducted to include a white pixel in a color image sensor. A color image sensor that includes a white pixel may have increased light utilization efficiency. However, with regard to some patterns, a color that is not actually present is seen, and thus, a color reproduction characteristic of the color image sensor may be reduced.

### SUMMARY

Exemplary embodiments may address at least the above problems and/or disadvantages and other disadvantages not described above. Also, the exemplary embodiments are not required to overcome the disadvantages described above, and may not overcome any of the problems described above.

Exemplary embodiments provide image sensors having hybrid color filters, whereby a clear color image may be provided under low intensity illumination conditions. According to an aspect of an exemplary embodiment, there is provided an image sensor including a photoelectric conversion layer, and color filters disposed on the photoelectric conversion layer and respectively in pixel regions, the color filters including a blue filter, a red filter, and a broad green filter. The blue filter includes an organic material, the red filter includes an organic material, and the broad green filter includes sub-micron structures including an inorganic material and disposed on the photoelectric conversion layer, and a dielectric layer covering the sub-microns structures, each of the sub-micron structures having a refractive index greater than a refractive index of the dielectric layer.

Each of the sub-micron structures may have a length in a range from about 50 nm to about 300 nm.

Each of the sub-micron structures may have an aspect ratio in a range from about 1 to about 6.

Each of the sub-micron structures may include one of titanium oxide, polysilicon, and amorphous silicon.

The dielectric layer may include one of silicon oxide, silane-based glass, polymethyl methacrylate, an epoxy resin, 2-Methoxy-1-methylethyl acetate, and phenylmethyl siloxane polymer.

The color filters may include color pixel units arranged in a matrix, and each of the color pixel units may include two broad green filters, a red filter, and a blue filter that are arranged in a 2×2 array, the two broad green filters being disposed in a diagonal direction in the 2×2 array.

The image sensor may further include an anti-reflection layer disposed between the photoelectric conversion layer and the color filters.

The image sensor may further include a micro-lens layer disposed on the color filters.

According to an aspect of another exemplary embodiment, there is provided an image sensor including a photoelectric conversion layer, and color filters disposed on the photoelectric conversion layer and respectively in pixel regions, the color filters including a blue filter, a red filter, and a broad green filter. The image sensor further includes a light transmitting layer disposed on the color filters, and a color splitter disposed over the broad green filter and in the photoelectric conversion layer, and configured to transmit a portion of incident light to the broad green filter, and refract a remaining portion of the incident light to the blue filter and the red filter. The blue filter includes an organic material, the red filter includes an organic material, and the broad green filter includes sub-micron structures including an inorganic material and disposed on the photoelectric conversion layer, and a dielectric layer covering the sub-microns structures, each of the sub-micron structures having a refractive index greater than a refractive index of the dielectric layer.

Each of the sub-micron structures may have a column shape.

Each of the sub-micron structures may have a length in a range from about 50 nm to about 300 nm.

Each of the sub-micron structures may have an aspect ratio of in a range from about 1 to about 6.

Each of the sub-micron structures may include one of titanium oxide, polysilicon, and amorphous silicon.

The dielectric layer may include one of silicon oxide, silane-based glass, polymethyl methacrylate, an epoxy resin, 2-Methoxy-1-methylethyl acetate, and phenylmethyl siloxane polymer.

The color filters may include color pixel units arranged in a matrix, and each of the color pixel units may include two broad green filters, a red filter, and a blue filter that are arranged in a 2×2 array, the two broad green filters being disposed in a diagonal direction in the 2×2 array.

The image sensor may further include an anti-reflection layer disposed between the photoelectric conversion layer and the color filters.

The image sensor may further include a micro-lens layer disposed on the color filters.

The color splitter may include a high refraction material including one of TiO₂, SiN₃, ZnS, ZnSe, and Si₃N₄.

The light transmitting layer may include one of silicon oxide and siloxane-based spin on glass.

### BRIEF DESCRIPTION OF THE DRAWINGS

The above and/or other aspects will become apparent and more readily appreciated from the following description of exemplary embodiments, taken in conjunction with the accompanying drawings in which:

FIG. 1 is a plan view of a pixel array of an image sensor according to an exemplary embodiment;

FIG. 2 is a cross-sectional view taken along a line II-II′ of FIG. 1;

FIG. 3 is a cross-sectional view of a barrier of FIG. 2;

FIG. 4 is a graph showing quantum efficiency of an image sensor having a white pixel of the related art, according to wavelengths;

FIG. 5 is a graph showing quantum efficiency of an image sensor having a broad green pixel, according to wavelengths, according to an exemplary embodiment;

FIGS. 6A, 6B, and 6C are plan views of pixel arrays according to other exemplary embodiments;

FIG. 7 is a plan view of a pixel array of an image sensor according to another exemplary embodiment; and

FIG. 8 is a cross-sectional view taken along a line VIII-VIII′ of FIG. 7.

### DETAILED DESCRIPTION

Exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions may not be described in detail because they would obscure the description with unnecessary detail.

In the drawings, thicknesses of layers and regions may be exaggerated for clarity of explanation. The exemplary embodiments may have different forms and may not be construed as being limited to the descriptions set forth herein.

It will be understood that when an element or layer is referred to as being “on” or “above” another element or layer, the element or layer may be directly on another element or layer or intervening elements or layers.

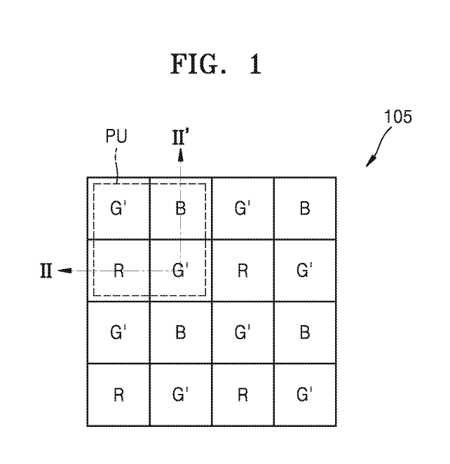

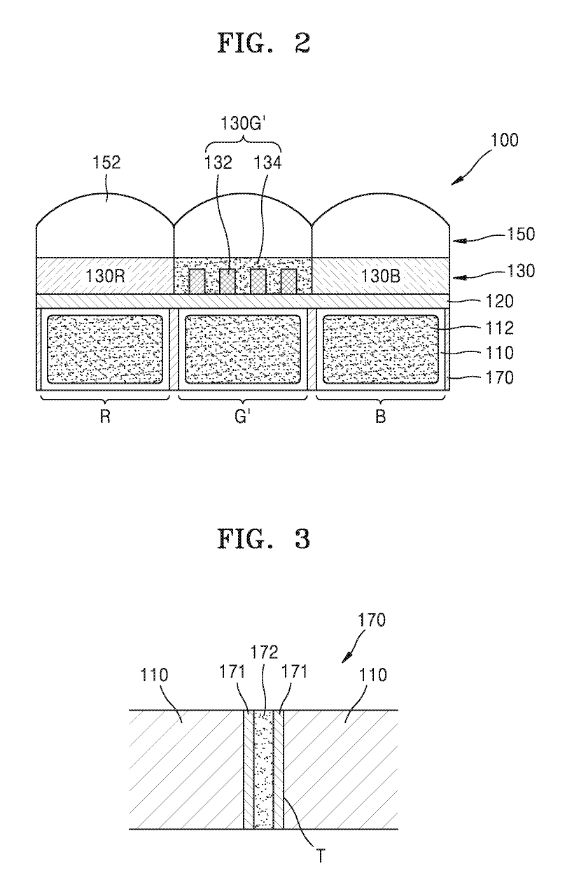

FIG. 1 is a plan view of a pixel array 105 of an image sensor 100 according to an exemplary embodiment. FIG. 2 is a cross-sectional view taken along a line II-II′ of FIG. 1.

Referring to FIG. 1, the pixel array 105 may include a plurality of pixel units (PUs) arranged in a matrix. Each of the PUs may include two broad green pixels G′, a red pixel R, and a blue pixel B. The broad green pixel G′, the red pixel R, and the blue pixel B may be referred to as pixel regions R, G′, and B, respectively. The broad green pixel G′ will be described in detail below.

FIG. 1 shows an example of the pixel array 105 in which a green pixel of a Bayer pattern is replaced with the broad green pixel G′, but the exemplary embodiment is not limited thereto. For example, the arrangement of the color pixels R, G′, and B may be different from the arrangement of FIG. 1. Also, each of the PUs may include cyan, yellow, broad green, and magenta pixels.

Referring to FIG. 2, the image sensor 100 may include a plurality of color filters 130 arranged on a photoelectric conversion layer 110. The color filters 130 may include a red filter 130R, a broad green filter 130G′, and a blue filter 130B. The color filters 130 below the respective PU constitute a color filter unit. The color filters 130 may be spaced apart from each other to prevent color crosstalk therebetween.

An anti-reflection layer 120 may be formed between the photoelectric conversion layer 110 and the color filters 130. A micro-lens layer 150 may be formed on the color filters 130. The anti-reflection layer 120 may have a structure in which a plurality of dielectric thin films, for example, a silicon oxide layer and a silicon nitride layer are stacked.

The photoelectric conversion layer 110 may include a plurality of photoelectric conversion regions 112 corresponding to the color pixels R, G′, and B. The photoelectric conversion layer 110 may be a silicon layer doped with a first type impurity, and the photoelectric conversion regions 112 may be regions doped with a second type impurity. If the first type impurity is an n-type impurity, the second type impurity may be a p-type impurity, or vice versa.

The blue filter 130B and the red filter 130R transmit light of corresponding colors and absorb light of other colors. The broad green filter 130G′ reflects or absorbs most of blue light and red light and transmits green light after receiving white light.

The blue filter 130B and the red filter 130R may be formed of organic material or dyes, and the broad green filter 130G′ may be formed of an inorganic material. For example, the blue filter 130B may include a coumarin-based dye, a tris-8-hydroxyquinolines Al (Alq3)-based dye or a merocyanine-based dye. The red filter 130R may include a phthalocyanine-based dye.

The broad green filter 130G′ may include a plurality of sub-micron structures 132 and a dielectric layer 134 that covers the sub-micron structures 132. The sub-micron structures 132 may be formed of a material having a refractive index greater than that of the dielectric layer 134. The sub-micron structures 132 may be formed of, for example, polysilicon or amorphous silicon. Also, the sub-micron structures 132 may be formed of titanium oxide.

The sub-micron structures 132 may have a column shape. The sub-micron structures 132 may have a length in a range from about 50 nm to about 300 nm. The sub-micron structures 132 may have an aspect ratio in a range from about 1 to about 6. The sub-micron structures 132 may be arranged with a gap of approximately 50 nm or more. The sub-micron structures 132 may be arranged with a periodical or non-periodical pattern.

The length of the sub-micron structures 132 may denote: a diameter if the shape of a cross-section is a circle; a diagonal length if the shape of the cross-section is a rectangle; and a longer diameter if the shape of the cross-section is an oval. Also, the length may denote the longest diagonal length if the shape of the cross-section is a polygon.

The dielectric layer 134 may be formed of a material having a refraction index lower than that of the sub-micron structures 132. For example, the dielectric layer 134 may be formed of silicon oxide or a silane-based glass. Also, the dielectric layer 134 may be formed of polymethyl methacrylate (PMMA), an epoxy resin, 2-Methoxy-1-methylethyl acetate, phenylmethyl siloxane polymer, etc.

The color filter of the image sensor 100 according to the exemplary embodiment may be formed of an organic or inorganic material, and hereinafter, the color filter will be referred to as a hybrid color filter.

The micro-lens layer 150 may include a plurality of micro-lenses 152. The micro-lenses 152 are formed on the color filters 130R, 130G′, and 130B to collect incident light and to send the collected incident light to the corresponding color filters 130R, 130G′, and 130B.

Barriers 170 that divide the pixels R, G′, and B may be formed in the photoelectric conversion layer 110 of the image sensor 100. The barriers 170 may vertically pass through the photoelectric conversion layer 110.

FIG. 3 is a cross-sectional view of a structure of the barrier 170 of FIG. 2. Referring to FIG. 3, each of the barriers 170 may include a trench T that divides and confines the pixels R, G′, and B, an insulating layer 171 that covers an inner wall of the trench T, and a light absorption layer 172 that fills a hole formed by the insulating layer 171. The insulating layer 171 may be formed of, for example, thin silicon oxide. The light absorption layer 172 may be formed of, for example, polysilicon. The light absorption layer 172 may be omitted.

The barriers 170 prevents incident light that enters a pixel from also entering an adjacent pixel, thereby preventing the occurrence of noise in the adjacent pixel. That is, the insulating layer 171 reflects light incident to an adjacent pixel after the light entering a single pixel, and light that passes through the insulating layer 171 may be absorbed by the light absorption layer 172.

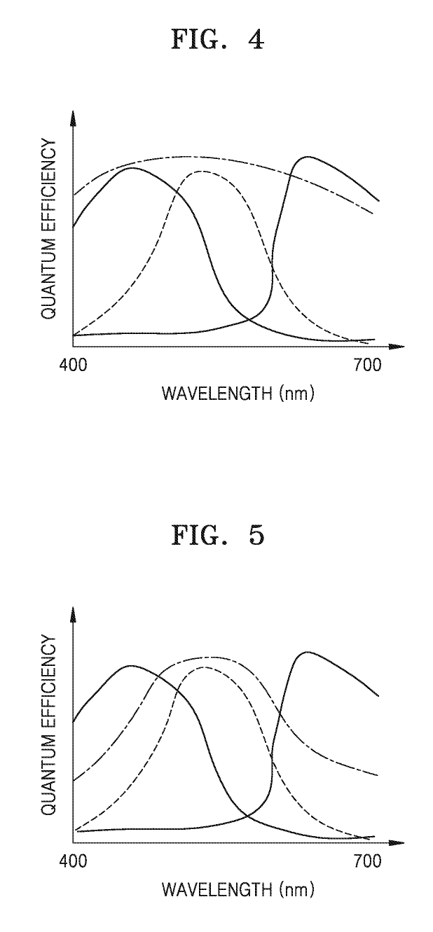

FIG. 4 is a graph showing quantum efficiency of an image sensor having a white pixel of the related art, according to wavelengths. A dot line shows quantum efficiency of a green pixel of the related art.

Referring to FIG. 4, it is seen that a spectrum (a curve of dash-dot line of FIG. 4) according to the white pixel has a small change of quantum efficiency according to wavelengths. When a color is realized by using the spectrum of the white pixel, a green is realized by subtracting light intensity of red pixel and blue pixel of the pixel unit from the intensity of the white pixel itself. However, a value of an off-diagonal element in a color correction matrix (CCM) becomes large in a process of color correction by using the CCM. As a result, a signal to noise ratio (SNR) is reduced. Equation 1 shows an example of a CCM of an image sensor that uses a white pixel.

$$[ \begin{matrix}R 1 \\ G 1 \\ B 1\end{matrix} ] = [ \begin{matrix}1.63 & - 0.54 & - 0.11 \\ - 0.84 & 3.23 & - 0.52 \\ 0.16 & - 1.1 & 1.9\end{matrix} ] [ \begin{matrix}R {1}^{′} \\ G {1}^{′} \\ B {1}^{′}\end{matrix} ] \qquad [ Equation 1 ]$$

In Equation 1, R1, G1, and B1 are values after correction, and R1′, G1′, and B1′ are values before correction.

FIG. 5 is a graph showing quantum efficiency of an image sensor having a broad green pixel, according to wavelengths, according to an exemplary embodiment. A dot line is a curve showing a quantum efficiency of a green pixel of the related art.

Referring to FIG. 5, a spectrum (a curve of dash dot line of FIG. 5) according to a broad green pixel is shaped similar to the spectrum of the green pixel of the related art, and the quantum efficiency of the broad green pixel is not much different from that of the green pixel of the related art. Accordingly, when a color is realized by using the spectrum according to the broad green pixel, a value of off-diagonal element of a CCM is, as shown in Equation 2, relatively small when compared to the Equation 1 in a process of color correction by using the CCM. As a result, an SNR is increased.

$$[ \begin{matrix}R 2 \\ G 2 \\ B 2\end{matrix} ] = [ \begin{matrix}1.33 & - 0.3 & - 0.11 \\ - 0.44 & 2.06 & - 0.75 \\ 0.09 & - 0.69 & 1.5\end{matrix} ] [ \begin{matrix}R {2}^{′} \\ G {2}^{′} \\ B {2}^{′}\end{matrix} ] \qquad [ Equation 2 ]$$

In Equation 2, R2, G2, and B2 are values after correction, and R2′, G2′, and B2′ are values before correction.

The image sensor 100 according to the current exemplary embodiment may take a clear image under a low illumination. Also, noise value is reduced when a green pixel is corrected by using a broad green pixel instead of a white pixel.

The arrangement of the pixel array 105 of the image sensor 100 depicted in FIG. 1 is an example to facilitate understanding, and the arrangement according to the exemplary embodiment is not limited to the arrangement of FIG. 1.

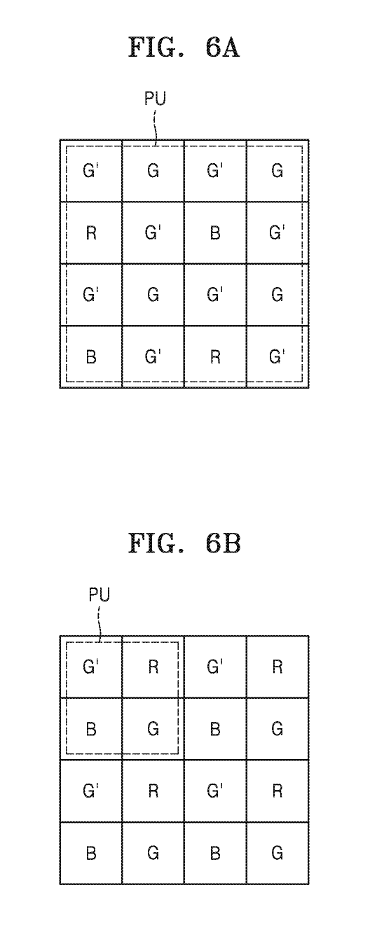

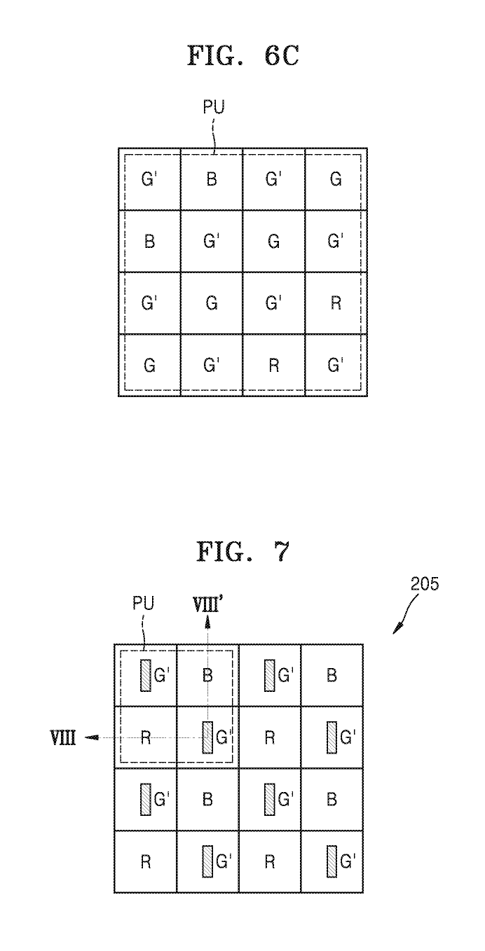

FIGS. 6A, 6B, and 6C are plan views of pixel arrays according to other exemplary embodiments. Each pixel unit (PU) uses a broad green pixel instead of a white pixel. The image sensors according to the other exemplary embodiments use a broad green pixel, and thus, have improved color clarity when compared to an image sensor that uses a white pixel of the related art.

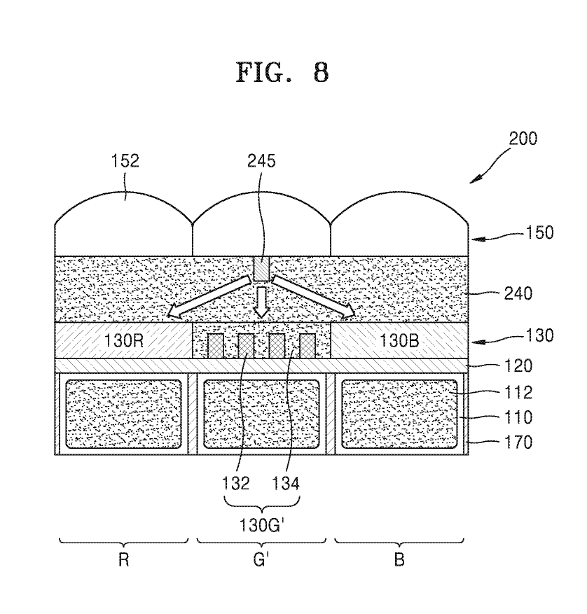

FIG. 7 is a plan view of a pixel array 205 of an image sensor 200 according to another exemplary embodiment. FIG. 8 is a cross-sectional view taken along a line VIII-VIII′ of FIG. 7. Like reference numerals are used for constituent elements that are substantially identical to the structure of FIGS. 1 and 2, and the descriptions thereof will not be repeated.

Referring to FIG. 7, the pixel array 205 includes a plurality of PUs arranged in a matrix. The PUs may include two broad green pixels G′, a single red pixel R, and a single blue pixel B. The pixels R, G′, and B may also be referred to as pixel regions R, G′, and B. The broad green pixel G′ will be described below.

The pixel array 205 of FIG. 7, as an example, shows that green pixels of a Bayer pattern are substituted by broad green pixels, but the current exemplary embodiment is not limited thereto. For example, the locations of the color pixels R, G′, and B may be different from the arrangement of FIG. 7. Also, the PUs may include cyan, yellow, broad green, and magenta pixels.

Referring to FIG. 8, the image sensor 200 may include a plurality of color filters 130 arranged on a photoelectric conversion layer 110. An anti-reflection layer 120 may be formed between the photoelectric conversion layer 110 and the color filters 130. A light transmitting layer 240 is formed on the color filters 130. A color splitter 245 is disposed in a broad green pixel region G′ of the light transmitting layer 240. A micro-lens layer 150 including micro-lenses 152 may be formed on the light transmitting layer 240.

The photoelectric conversion layer 110 may include a plurality of photoelectric conversion regions 112 corresponding to the color pixels R, G′, and B.

A blue filter 130B and a red filter 130R transmit light of corresponding colors and blocks light of other colors. A broad green filter 130G′ reflects or absorbs most of blue light and red light and transmits green light after receiving white light.

The light transmitting layer 240 may provide paths for lights separated by the color splitter 245 to reach corresponding pixels. The light transmitting layer 240 may be a transparent dielectric layer. The light transmitting layer 240 may be formed of SiO₂ or siloxane-based spin on glass (SOG). The light transmitting layer 240 may be designed to move the lights separated by the color splitter 245 to the corresponding color filters 130.

The color splitter 245 is disposed on a light incident side of the light transmitting layer 240 in the broad green pixel region G′, transmits green light, and inputs magenta light that includes blue light and red light to adjacent pixel regions. The color splitter 245 may separate colors by changing proceeding paths of light according to wavelengths of the incident light by using diffraction and refraction characteristics of light that varies according to the wavelengths. The color splitter 245 may be formed of a material having a refractive index greater than that of the light transmitting layer 240. For example, the light transmitting layer 240 may include SiO₂ or SOG, and the color splitter 245 may include a material having a high refractive index, such as TiO₂, SiN₃, ZnS, ZnSe, or Si₃N₄. The color splitters 245 may have well-known various shapes, for example, a bar shape having a transparent symmetrical or non-symmetrical structure or a prism shape having an inclined plane. Also, the color splitters 245 may be designed in various ways according to a desired spectrum distribution of emitted light.

Hereinafter, an operation of the image sensor 200 will be described with reference to FIGS. 7 and 8.

Incident light that enters the image sensor 200 is focused by the micro-lenses 152 and enters the light transmitting layer 240. Incident light that enters the light transmitting layer 240 respectively enters corresponding color filters 130R, 130G′, and 130B. Incident light that enters the light transmitting layer 240 of the broad green pixel 130G′ is separated to green light and remaining color of light, for example, magenta light by passing through the color splitter 245. The magenta light includes red light and blue light. Of the light that enters the broad green pixel G′, the green light enters the broad green filter 130G′ without changing direction, and remaining light is slantly refracted at the color splitter 245 and enters adjacent regions, that is, the red filter 130R and the blue filter 130B.

Accordingly, the magenta light that is refracted from the color splitter 245 disposed above the broad green pixel G′ adjacent to the red pixel R and the blue pixel B may further enter the red pixel R and the blue pixel B besides the light incident to the corresponding pixels R and B. Accordingly, the light utilization efficiency in the red pixel R and the blue pixel B may be increased.

In the broad green pixel G′, a portion of the magenta light may enter besides the green light. The intensity of light that passes through the broad green filter 130G′ may be increased more than the intensity of light that passes through a green filter of the related art. Accordingly, a color image photographing at a low illumination condition may be possible.

The arrangements of the pixel array 205 and the color splitter 245 of the image sensor 200 depicted in FIGS. 7 and 8 are examples to facilitate understanding, and the current exemplary embodiment is not limited thereto. Various color separation characteristics may be selected according to the design of the color splitter 245, and the structure of the pixel array 205 may also be selected in various ways according to the color separation characteristics of the color splitter 245.

In the image sensor according to the exemplary embodiment, light utilization efficiency is increased by using a color splitter, and a clear image may be photographed at a low illumination condition.

The image sensor according to the exemplary embodiment uses a broad green pixel instead of a white pixel, and thus, a noise value is reduced when the green pixel is corrected. Also, an image having a high definition may be photographed at a low illumination condition.

Also, the light utilization efficiency is increased by using a color splitter.

While exemplary embodiments have been described with reference to the figures, it will be understood by those of ordinary skill in the art that various changes in form and details may be made therein without departing from the spirit and scope as defined by the following claims.

What is claimed is:

1. An image sensor comprising:
a photoelectric conversion layer; and
color filters disposed on the photoelectric conversion layer and respectively in pixel regions, the color filters comprising a blue filter, a red filter, and a broad green filter,
wherein the blue filter comprises an organic material,
the red filter comprises an organic material, and
the broad green filter comprises sub-micron structures comprising an inorganic material and disposed on the photoelectric conversion layer, and a dielectric layer covering the sub-microns structures, each of the sub-micron structures having a refractive index greater than a refractive index of the dielectric layer.

2. The image sensor of claim 1, wherein each of the sub-micron structures has a column shape.

3. The image sensor of claim 2, wherein each of the sub-micron structures has a length in a range from about 50 nm to about 300 nm.

4. The image sensor of claim 2, wherein each of the sub-micron structures has an aspect ratio in a range from about 1 to about 6.

5. The image sensor of claim 2, wherein each of the sub-micron structures comprises one of titanium oxide, polysilicon, and amorphous silicon.

6. The image sensor of claim 2, wherein the dielectric layer comprises one of silicon oxide, silane-based glass, polymethyl methacrylate, an epoxy resin, 2-Methoxy-1-methylethyl acetate, and phenylmethyl siloxane polymer.

7. The image sensor of claim 1, wherein the color filters comprise color pixel units arranged in a matrix, and
each of the color pixel units comprises two broad green filters, a red filter, and a blue filter that are arranged in a 2×2 array, the two broad green filters being disposed in a diagonal direction in the 2×2 array.

8. The image sensor of claim 1, further comprising an anti-reflection layer disposed between the photoelectric conversion layer and the color filters.

9. The image sensor of claim 1, further comprising a micro-lens layer disposed on the color filters.

10. An image sensor comprising:
a photoelectric conversion layer;
color filters disposed on the photoelectric conversion layer and respectively in pixel regions, the color filters comprising a blue filter, a red filter, and a broad green filter;
a light transmitting layer disposed on the color filters; and
a color splitter disposed over the broad green filter and in the photoelectric conversion layer, and configured to transmit a portion of incident light to the broad green filter, and refract a remaining portion of the incident light to the blue filter and the red filter,
wherein the blue filter comprises an organic material,
the red filter comprises an organic material, and
the broad green filter comprises sub-micron structures comprising an inorganic material and disposed on the photoelectric conversion layer, and a dielectric layer covering the sub-microns structures, each of the sub-micron structures having a refractive index greater than a refractive index of the dielectric layer.

11. The image sensor of claim 10, wherein each of the sub-micron structures has a column shape.

12. The image sensor of claim 11, wherein each of the sub-micron structures has a length in a range from about 50 nm to about 300 nm.

13. The image sensor of claim 11, wherein each of the sub-micron structures has an aspect ratio of in a range from about 1 to about 6.

14. The image sensor of claim 11, wherein each of the sub-micron structures comprises one of titanium oxide, polysilicon, and amorphous silicon.

15. The image sensor of claim 11, wherein the dielectric layer comprises one of silicon oxide, silane-based glass, polymethyl methacrylate, an epoxy resin, 2-Methoxy-1-methylethyl acetate, and phenylmethyl siloxane polymer.

16. The image sensor of claim 10, wherein the color filters comprise color pixel units arranged in a matrix, and
each of the color pixel units comprises two broad green filters, a red filter, and a blue filter that are arranged in a 2×2 array, the two broad green filters being disposed in a diagonal direction in the 2×2 array.

17. The image sensor of claim 10, further comprising an anti-reflection layer disposed between the photoelectric conversion layer and the color filters.

18. The image sensor of claim 10, further comprising a micro-lens layer disposed on the color filters.

19. The image sensor of claim 10, wherein the color splitter comprises a high refraction material comprising one of TiO₂, SiN₃, ZnS, ZnSe, and Si₃N₄.

20. The image sensor of claim 10, wherein the light transmitting layer comprises one of silicon oxide and siloxane-based spin on glass.
